(19) United States
(12) Patent Application Publication
(10) Pub. No.: US 2019/0256986 A1
(43) Pub. Date: Aug. 22, 2019

(54) GE, SIGE OR GERMANIDE WASHING METHOD

(71) Applicants: INTERUNIVERSITY MICROELECTRONICS CENTRE, Leuven (BE); KURITA WATER INDUSTRIES LTD., Tokyo (JP)

(72) Inventors: Nobuko GAN, Tokyo (JP); Tatsuo NAGAI, Tokyo (JP); Farid SEBAAI, Leuven (BE); Kurt WOSTYN, Leuven (BE)

(21) Appl. No.: 16/347,458

(22) PCT Filed: Dec. 5, 2016
(86) PCT No.: PCT/JP2016/086014

§ 371 Date: May 3, 2019

(51) Int. Cl. C23G 1/10; B08B 3/08; H01L 21/02

(52) U.S. Cl. CPC C23G 1/10; H01L 21/02068; H01L 21/0206; B08B 3/08

(57) ABSTRACT

In a step of washing Ge, SiGe or germanide layers in the production of semiconductor devices, resists or metal residues are efficiently removed through washing without dissolving Ge, SiGe or germanides. A sulfuric acid solution with a sulfuric acid concentration of 90 wt % or more and an oxidant concentration of 200 g/L or less is used as a washing liquid. Examples of the washing liquid include an electrolytic solution obtained by electrolysis of the sulfuric acid solution, a solution obtained by mixing hydrogen peroxide with the acid solution or a solution obtained by dissolving an ozone gas in the sulfuric acid solution. A treatment temperature during the washing is preferably 50° C. or less.

### TECHNICAL FIELD

The present invention relates to a washing method for removing resists or metal residues on the surface of Ge, SiGe or germanides through washing in the production process of semiconductor devices. Specifically, the present invention relates to a washing method for efficiently removing resists or metal residues on the surface of Ge, SiGe or germanides through washing without dissolving Ge, SiGe or germanides.

### BACKGROUND ART

In recent years, channel materials are changing from Si to Ge, SiGe, silicides or germanides, as semiconductor devices are miniaturized, to improve the mobility of channels. The production process of devices using Ge, SiGe or germanides includes a washing step of removing resists or metal residues from a Ge layer, a SiGe layer or a germanide, in the same manner as in conventional production processes of Si semiconductors.

Conventionally, SPMs (Sulfuric acid-Hydrogen Peroxide Mixtures) are generally used for removing resists or metal residues on a Si channel or a silicide (PTLs 1 and 2).

When a Ge layer, SiGe layer or a germanide is washed using a SPM, the Ge, SiGe or germanide dissolves therein to deteriorate the electrical properties of devices.

### PTL 1: JP 2014-241386 A

### PTL 2: JP 2013-168576 A

### SUMMARY OF INVENTION

It is an object of the present invention to provide a method for washing Ge, SiGe or germanides, the method enabling resists or metal residues to be efficiently removed through washing without dissolving the Ge, SiGe or germanide in a step of washing Ge, SiGe or germanides in the production of semiconductor devices.

The inventors have found that resists or metal residues can be efficiently removed through washing without dissolving Ge, SiGe or germanides, using a sulfuric acid solution with a sulfuric acid concentration of a predetermined value or more and an oxidant concentration of a predetermined value or less as a washing liquid.

The gist of the present invention is as follows.

[1] A method for washing Ge, SiGe or a germanide to remove a resist and/or a metal residue on the Ge, SiGe or germanide, wherein a sulfuric acid solution with a sulfuric acid concentration of 90 wt % or more and an oxidant concentration of 200 g/L or less is used as a washing liquid.
[2] The method for washing Ge, SiGe or a germanide according to [1], wherein the washing liquid is an electrolytic solution obtained by electrolysis of the sulfuric acid solution.
[3] The method for washing Ge, SiGe or a germanide according to [1], wherein the washing liquid is a solution obtained by mixing hydrogen peroxide with the sulfuric acid solution.
[4] The method for washing Ge, SiGe or a germanide according to [1], wherein the washing liquid is a solution obtained by dissolving an ozone gas in the sulfuric acid solution.
[5] The method for washing Ge, SiGe or a germanide according to any one of [1] to [4], wherein a treatment temperature during the washing is 50° C. or less.

### Advantageous Effects of Invention

According to the present invention, resists or metal residues on Ge, SiGe or germanides can be efficiently removed through washing without dissolving the Ge, SiGe or germanide.

### BRIEF DESCRIPTION OF DRAWINGS

FIG. 1 is a graph showing the relationship between the sulfuric acid concentration and the Ge dissolution rate in each test solution in Experimental Example 1.

FIG. 2 is a graph showing the relationship between the oxidant concentration and the Ge dissolution rate in each test solution in Experimental Example 2.

FIG. 3 is a graph showing the relationship between the sulfuric acid concentration and the NiPt residue removal rate in each test solution in Experimental Example 3.

FIG. 4 is a graph showing the relationship between the sulfuric acid concentration and the resist removal rate in each test solution in Experimental Example 3.

FIG. 5 is a graph showing the relationships of the oxidant concentration to the NiPt residue removal rate and the resist removal rate in the ESA test solution in Experimental Example 4.

### DESCRIPTION OF EMBODIMENTS

Hereinafter, the embodiments of the present invention will be described in detail.

The inventors have investigated the causes of dissolution of Ge, SiGe or germanides in SPMs conventionally used for washing silicon wafers. As a result, they have found that, in the case of using an acidic solution containing an oxidant and moisture as a washing liquid for washing, the moisture in the washing liquid significantly affects the dissolution of Ge, SiGe or germanides. Generally, since sulfuric acid and a hydrogen peroxide solution (with a hydrogen peroxide concentration of 30 wt %) are mixed at a ratio of 3:1 to 5:1 (volume ratio) in the SPM, the SPM contains a considerable amount of moisture. Further, since the liquid temperature of the SPM after mixing becomes as high as 100° C. or more due to the exothermic reaction by mixing, Ge, SiGe or germanides vigorously dissolve in the SPM.

In order to remove resists or metal residues on Ge, SiGe or germanides, an oxidant is necessary. In the case of using a SPM, it is essential to reduce the moisture content in the washing liquid containing the oxidant as much as possible without reducing the oxidant concentration, in order to prevent the dissolution of Ge, SiGe or germanides.

In view of the aforementioned problems, the inventors have studied a new method for washing Ge, SiGe or germanides using an acidic washing liquid without dissolving Ge, SiGe or germanides. As a result, they have found that resists or metal residues can be highly removed through washing, while the dissolution of Ge, SiGe or germanides is sufficiently suppressed, by washing preferably at a treatment temperature of 50° C. or less using a sulfuric acid solution with a sulfuric acid concentration of 90 wt % or more and an oxidant concentration of 200 g/L or less.

In the present invention, Ge, SiGe or germanides to be washed is specifically a wafer to which resist films or metal residues after formation of germanide adhere in the course of forming an insulation film, an electrode film or the like on a Ge or SiGe film formed on a silicon wafer in the production process of semiconductor devices, and on the surface of which a Ge or SiGe film or a germanide layer is exposed. While such resists or metal residues on the wafer need to be reliably removed for the subsequent film-forming step, the dissolution of Ge, SiGe or germanides needs to be suppressed as much as possible. As SiGe, a SiGe alloy of about Si₁₋ₓGeₓ (0.5 x<1) is suitable.

In the present invention, a sulfuric acid solution with a sulfuric acid concentration of 90 wt % or more and an oxidant concentration of 200 g/L or less is used as a washing liquid for washing such Ge, SiGe or germanides.

A higher sulfuric acid concentration in the sulfuric acid solution as a washing liquid allows a relatively lower moisture concentration and thus can more highly suppress the dissolution of Ge, SiGe or germanides. It is preferable that the sulfuric acid concentration in the sulfuric acid solution used as a washing liquid be 90 wt % or more, particularly 96 wt % or more, and the moisture concentration be 10 wt % or less, particularly 4 wt % or less. The upper limit of the sulfuric acid concentration in the sulfuric acid solution is generally 98 wt %.

A sulfuric acid solution with a high sulfuric acid concentration and a low moisture concentration can suppress the dissolution of Ge, SiGe or germanides during washing.

In the present invention, the reason why the oxidant concentration of the washing liquid is set to 200 g/L or less is as follows.

An oxidant is a component necessary for removing resists or metal residues. As described above, a sulfuric acid solution with a sulfuric acid concentration of 90 wt % or more is used in the present invention for suppressing the dissolution of Ge, SiGe or germanides. In the case of using such a high-concentration sulfuric acid solution that has been electrolyzed to generate persulfuric acid as a washing liquid, it is difficult to increase the oxidant concentration to over 200 g/L in a common electrolytic device, due to poor electrolytic efficiency of the high-concentration sulfuric acid solution. In this case, a suitable oxidant concentration is 5 g/L or less.

In the case of using a sulfuric acid solution with an ozone gas dissolved therein as a washing liquid, the upper limit of the solubility of the ozone gas in the sulfuric acid solution is generally about 0.2 g/L, and thus it is difficult to adjust the sulfuric acid solution to have an oxidant concentration of over 5 g/L.

Generally, the hydrogen peroxide concentration in a hydrogen peroxide solution is 30 wt %, and therefore the sulfuric acid concentration in a general SPM is 90 wt % or less. Accordingly, the mixing ratio needs to be sufficiently controlled for preparing a SPM with a sulfuric acid concentration of 90 wt % or more.

From these viewpoints, an ESA or SOM that is capable of containing an oxidant while maintaining a high sulfuric acid concentration, which will be described below, is desirable as a washing liquid, as compared with conventional SPMs with a mixing ratio of 3:1 to 5:1.

When the oxidant concentration of the sulfuric acid solution as a washing liquid is excessively low, the efficiency in removing resists and metal residues is poor. In particular, the oxidant concentration necessary for completely removing resists or metal residues is 2 g/L or more, as shown in Experimental Example 4 below.

The moisture concentration of the sulfuric acid solution with a sulfuric acid concentration of 98 wt % and an oxidant concentration of 5 g/L used in Experimental Examples below is about 2 wt %.

The sulfuric acid solution used as a washing liquid in the present invention needs only to satisfy the oxidant concentration and the sulfuric acid concentration described above, and the type of the oxidant or the like is not particularly limited. Examples of the sulfuric acid solution used in the present invention specifically include the following.

(1) An electrolytic solution obtained by electrolysis of the sulfuric acid solution (hereinafter sometimes referred to as “ESA”)
(2) A SPM that is a solution obtained by mixing hydrogen peroxide with the sulfuric acid solution
(3) A solution obtained by dissolving an ozone gas in the sulfuric acid solution (hereinafter sometimes referred to as “SOM”)

The ESA is formed by electrolysis of the sulfuric acid solution to generate peroxodisulfate (H₂S₂O₈) that is persulfuric acid as an oxidant. The peroxodisulfate generated has high oxidative power, thereby separating and removing resists or metal residues.

The oxidant concentration in the ESA can be easily controlled by adjusting the electrolytic conditions.

It is preferable that the sulfuric acid solution having a reduced persulfuric acid concentration due to self-degradation of peroxodisulfate ions in the solution by use of the ESA as a washing liquid be regenerated by electrolysis so as to be recycled. In this case, the sulfuric acid solution with a reduced persulfuric acid concentration is fed from a washing device to an electrolytic device through a circulation line. In the electrolytic device, an anode and a cathode are brought into contact with the sulfuric acid solution to allow a current to flow between the electrodes for electrolysis, thereby generating peroxodisulfate ions through oxidation of sulfate ions or hydrogen sulfate ions, to regenerate a sulfuric acid solution with a desired persulfuric acid concentration. The persulfuric acid-containing sulfuric acid solution regenerated is returned to the washing device through the circulation line, so as to be reused for washing.

The persulfuric acid-containing sulfuric acid solution is circulated between the washing device and the electrolytic reactor, so that efficient washing can be continued while the peroxodisulfate ion composition of the persulfuric acid-containing sulfuric acid solution used for separation and washing is maintained at a concentration suitable for washing.

The SPM is prepared by mixing hydrogen peroxide with the sulfuric acid solution. The hydrogen peroxide is provided as a hydrogen peroxide solution with a hydrogen peroxide concentration of usually about 2 to 50 wt %, generally 30 wt %. As mentioned above, SPMs conventionally used for washing silicon wafers mix sulfuric acid with a 30-wt % hydrogen peroxide solution at a ratio (volume ratio) of 3:1 to 5:1, and therefore it is difficult to achieve a predetermined oxidant concentration, that is, a sulfuric acid concentration of 90 wt % or more. In the present invention, sulfuric acid is mixed with a 30-wt % hydrogen peroxide solution at a high mixing ratio of sulfuric acid, such as a mixing ratio of 10:1 or more (volume ratio), to give a SPM with a high sulfuric acid concentration, a low moisture concentration, and a predetermined oxidant concentration.

The SOM is prepared by blowing an ozone gas into sulfuric acid. When blowing the ozone gas into the sulfuric acid solution with a concentration of 90 wt % or more, the concentration of the ozone gas to be dissolved is generally 0.2 g/L or less, and it is difficult to adjust the sulfuric acid solution containing the ozone gas with a higher concentration.

Therefore, a SPM or ESA is preferably used as a washing liquid in the present invention, in view of the efficiency in removing resists and metal residues. In particular, the ESA can perform washing while maintaining a desired oxidant (peroxodisulfate ion) concentration by circulation between the electrolytic device and the washing device, as mentioned above, and thus is industrially advantageous.

In the present invention, Ge, SiGe or germanides are washed using the sulfuric acid solution containing an oxidant as mentioned above as a washing liquid. The treatment temperature (washing liquid temperature) during washing is preferably 50° C. or less. Treatment at a high temperature is preferable for removing resists or metal residues, particularly removing resists, but a treatment temperature over 50° C. or more tends to drastically increase the dissolution rate of Ge, SiGe or germanides. Therefore, the treatment temperature during washing is preferably set as low as possible within the range in which resists or metal residues can be removed through washing, preferably within a range of 30 to 50° C.

The washing time is preferably set shorter within the range in which resists or metal residues can be removed, for suppressing the dissolution of Ge, SiGe or germanides. The preferable washing time also depends on the sulfuric acid concentration of the sulfuric acid solution used as a washing liquid and the treatment temperature but is preferably within 2 minutes, particularly within 1 minute, for example, 30 seconds to 1 minute.

### EXAMPLES

Hereinafter, the present invention will be more specifically described by way of Experimental Examples instead of Examples.

### <Test Item Conditions>

The following items were determined according to the purpose of the test.

(1) Sulfuric acid concentration
(2) Oxidant concentration
(3) Treatment temperature
(4) Treatment time

### <Sample Conditions>

The following 3 types of wafers were used.

(1) 20-nm NiPtGe/300-mm Si (Pt content: 5 wt %) with 50-nm NiPt
residues attached

### (2) Epitaxial 80-nm Ge/300-mm Si

(3) Epitaxial 80-nm Ge/300-mm Si with resists attached

The aforementioned sample (1) has a 20-nm thick NiPtGe film (Pt content 5 wt %) on a 300-mm diameter Si wafer with 50-nm thick NiPt residues attached.

The aforementioned sample (2) is an 80-nm thick epitaxial Ge film formed on the surface of a 300-mm diameter Si wafer.

The aforementioned sample (3) is the aforementioned sample (2) with resists further attached.

### <Analysis Method>

(1) ICP-MS: To analyze Ge, SiGe, metal concentration in a test solution
(2) Microscopy: To analyze the resist removal rate on Ge

### <Test Flow>

Each 300-mm wafer is cut into a 25-mm square test piece. The cut test piece is immersed in each test solution for a predetermined time. After the immersion, the test solution is analyzed by ICP-MS or the like to calculate a NiPt residue removal rate or Ge dissolution rate from the eluted metal concentration. Alternatively, the degree of removal of resists on the test piece is investigated by microscopy.

### Experimental Example 1

The Ge solubility depending on the difference in sulfuric acid concentration of each test solution was tested.

### Test Conditions:

(1) Test solution: Sulfuric acid (sulfuric acid aqueous solution), ESA, SPM or SOM
(2) Sulfuric acid concentration: 30 to 98 wt %
(3) Oxidant concentration: 5 g/L (in the ESA or SPM), 0.2 g/L (in the SOM) or 0 g/L (in sulfuric acid)
(4) Treatment temperature: 30° C.
(5) Immersion time: 30 seconds
(6) Wafer used: Epitaxial 80-nm Ge/300-mm Si

Analysis method: ICP-MS (to analyze the Ge concentration in the test solution)

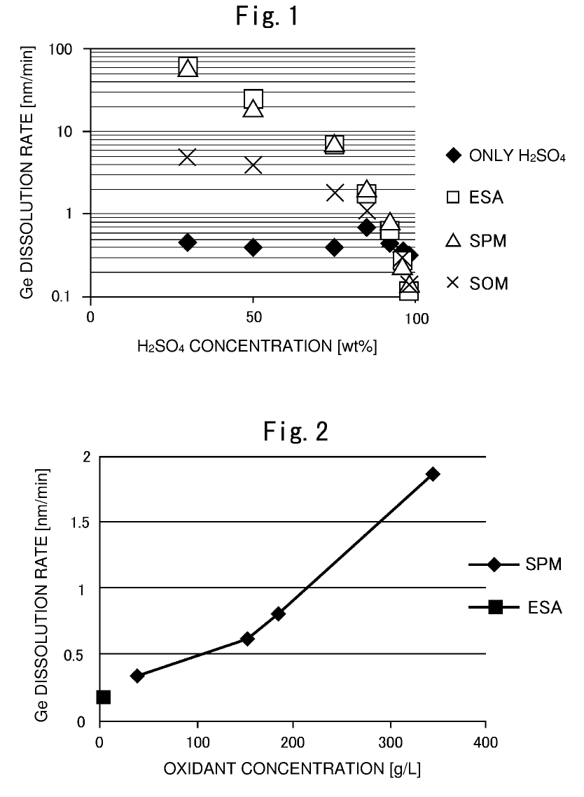

### Results: Shown in FIG. 1

The following facts are shown from FIG. 1.

In the presence of only sulfuric acid and the absence of oxidants, the Ge dissolution rate is 1 nm/min or less. In the presence of oxidants, the Ge dissolution rate is inversely proportional to the sulfuric acid concentration in the test solution (the Ge dissolution rate is proportional to the moisture content in the test solution). For reducing the Ge dissolution rate to 1 nm/min or less, the sulfuric acid concentration in the test solution needs to be 90 wt % or more.

The Ge dissolution rate in the SOM is lower than that in the ESA or SPM. However, since the oxidative power of the SOM is lower than that of the ESA or SPM, as shown in Experimental Example 3, resists or metal residues cannot be completely removed with the SOM.

Since the sulfuric acid concentration and the oxidant concentration in the SPM vary depending the use in a batch-type washing machine or time elapsed, the amount of Ge, SiGe or germanides to be dissolved is not stable. Accordingly, the ESA is most desirable as a washing liquid for controlling the amount of Ge, SiGe or germanides to be dissolved.

### Experimental Example 2

The Ge solubility depending on the difference in oxidant concentration in the test solution was tested.

### Test Conditions:

(1) Test solution: ESA or SPM
(2) Sulfuric acid concentration: 85 to 98 wt %
(3) Oxidant concentration: 5 g/L (in the ESA) or 3 to 350 g/L (in the SPM)
(4) Treatment temperature: 30° C.
(5) Immersion time: 60 seconds
(6) Wafer used: Epitaxial 80-nm Ge/300-mm Si
Analysis method: ICP-MS (to analyze the Ge concentration in the test solution)

### Results: Shown in FIG. 2

The following facts are shown from FIG. 2.

With an oxidant concentration of over 200 g/L, the Ge dissolution rate is over 1 nm/min, and therefore it is not suitable in view of high integration of semiconductors. The oxidant concentration is preferably 200 g/L or less.

### Experimental Example 3

The removability of NiPt residues or resists depending on the difference in sulfuric acid concentration in the test solution was tested.

### Test Conditions:

(1) Test solution: Sulfuric acid (sulfuric acid aqueous solution), ESA, SPM or SOM
(2) Sulfuric acid concentration: 30 to 98 wt %
(3) Oxidant concentration: 5 g/L (in the ESA or SPM), 0.2 g/L (in the SOM) or 0 g/L (in sulfuric acid)
(4) Treatment temperature: 30° C. (in the case of removing a NiPt residue) or 50° C. (in the case of removing a resist)
(5) Immersion time: 30 seconds
(6) Wafer used: 20-nm NiPtGe/300-mm Si (Pt content: 5 wt %) with 50-nm NiPt residues attached or Epitaxial 80-nm Ge/300-mm Si with resists attached
Analysis method: ICP-MS (to analyze the Ni/Pt concentration in the test solution) or microscopy (to analyze the resist removal rate)

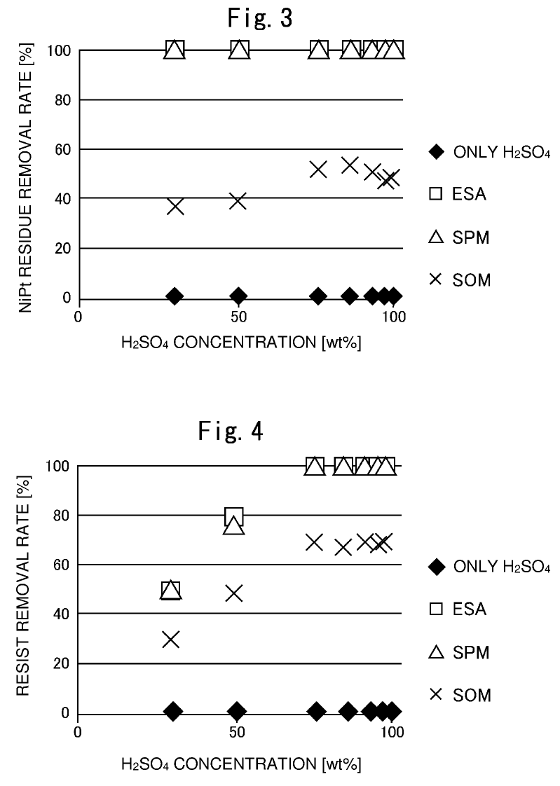

### Results: Shown in FIG. 3 and FIG. 4

The following facts are shown from FIG. 3 and FIG. 4.

The resists or the NiPt residues were not removed using only sulfuric acid, and an oxidant was needed for removing the resists or the NiPt residues. The resists were removed using the ESA or SPM with a sulfuric acid concentration of 75 wt % or more. The NiPt residues were removed using the ESA or SPM regardless of the sulfuric acid concentration. However, since the oxidant concentration in the SOM in this treatment was low, the resists and the NiPt residues were not sufficiently removed with the SOM.

It has been revealed from this experimental example that the ESA or SPM with a sulfuric acid concentration of 75 wt % or more is effective for removing the resists and the NiPt residues.

However, as shown in Experimental Example 1, the ESA or SPM with a sulfuric acid concentration of 90 wt % or more needs to be used for reducing the dissolution rate of Ge, SiGe or germanides.

### Experimental Example 4

The removability of resists or NiPt residues depending on the difference in oxidant concentration in the ESA was tested.

### Test Conditions:

(1) Test solution: ESA
(2) Sulfuric acid concentration: 96 wt %
(3) Oxidant concentration: 0 to 5 g/L
(4) Treatment temperature: 30° C. (in the case of removing NiPt residues) or 50° C. (in the case of removing resists)
(5) Immersion time: 30 seconds
(6) Wafer used: 20-nm NiPtGe/300-mm Si (Pt content: 5 wt %) with 50-nm NiPt residues attached or Epitaxial 80-nm Ge/300-mm Si with resists attached

Analysis method: ICP-MS (to analyze the Ni/Pt concentration in the test solution) or microscopy (to analyze the resist removal rate)

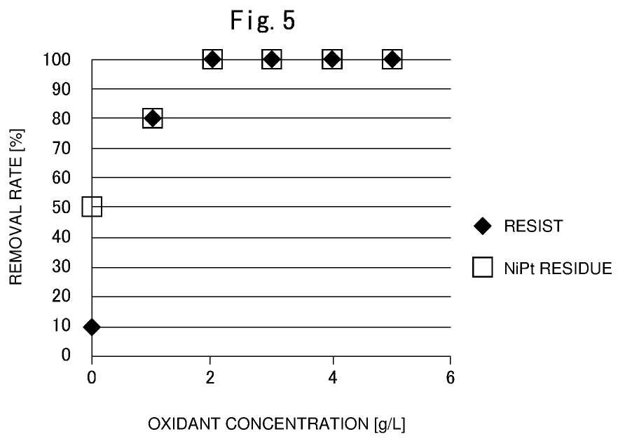

Results: shown in FIG. 5

The following facts are shown from FIG. 5.

The removal rate of the resists or NiPt residues is proportional to the oxidant concentration. In the production of semiconductor devices, even a trace amount of resists or NiPt residues remaining decreases the yield, and therefore the resists or NiPt residues need to be completely removed. Therefore, a test solution with an oxidant concentration of 2 g/L or more is necessary. Further, as described in Experimental Example 1, an ESA or SPM with a sulfuric acid concentration of 90 wt % or more should be used for preventing the dissolution of Ge, SiGe or germanides. In the case of electrolyzing 90 wt % or more of sulfuric acid, the efficiency of generating peroxosulfuric acid decreases, and thus the oxidant concentration should be about 5 g/L at maximum, in consideration of the price of an ESA production apparatus. Accordingly, a suitable oxidant concentration is 5 g/L or less.

In the SPM, the oxidant concentration increases, as hydrogen peroxide is mixed. However, the moisture content in the SPM increases due to the addition of hydrogen peroxide, and the dissolution of Ge, SiGe or germanides is accelerated. Accordingly, an ESA or SPM with a sulfuric acid concentration of 90 wt % or more and an oxidant concentration of 5 g/L or less is optimal for removing resists or NiPt residues on Ge, SiGe or germanides.

### Experimental Example 5

The Ge solubility depending on the difference in treatment temperature was tested.

### Test Conditions:

(1) Test solution: ESA
(2) Sulfuric acid concentration: 98 wt %
(3) Oxidant concentration: 2 g/L
(4) Treatment temperature: 30, 40, 50 or 60° C.
(5) Immersion time: 15, 30 or 60 seconds
(6) Wafer used: Epitaxial 80-nm Ge/300-mm Si
Analysis method: ICP-MS (to analyze the Ge concentration in the test solution)

### Results:

The treatment temperature obviously affected the Ge dissolution rate. In the case of treatment at 50° C., the Ge dissolution rate was 1 nm/min or less. In the case of treatment at 60° C., the Ge dissolution rate was over 1 nm/min. Therefore, it is understood that the treatment temperature is preferably 50° C. or less.

Although the present invention has been described in detail using specific embodiments, it will be apparent to those skilled in the art that various modifications are possible without departing from the spirit and scope of the invention.

This application is based on Japanese Patent Application No. 2015-118463 filed on Jun. 11, 2015, which is incorporated by reference in its entirety.

1. A method for washing Ge, SiGe or a germanide to remove a resist and/or a metal residue on the Ge, SiGe or germanide, wherein
a sulfuric acid solution with a sulfuric acid concentration of 90 wt % or more and an oxidant concentration of 200 g/L or less is used as a washing liquid.

2. The method for washing Ge, SiGe or a germanide according to claim 1, wherein
the washing liquid is an electrolytic solution obtained by electrolysis of the sulfuric acid solution.

3. The method for washing Ge, SiGe or a germanide according to claim 1, wherein
the washing liquid is a solution obtained by mixing hydrogen peroxide with the sulfuric acid solution.

4. The method for washing Ge, SiGe or a germanide according to claim 1, wherein
the washing liquid is a solution obtained by dissolving an ozone gas in the sulfuric acid solution.

5. The method for washing Ge, SiGe or a germanide according to claim 1, wherein
a treatment temperature during the washing is 50° C. or less.
